(19) United States
(12) Patent Application Publication
(10) Pub. No.: US 2011/0309895 A1
(43) Pub. Date: Dec. 22, 2011

(54) MULTILAYER FILTER

(75) Inventors: Young Ghyu AHN, Yongin (KR); Sang Soo Park, Suwon (KR); Dong Seok Park, Seoul (KR); Sung Jin Park, Busan (KR); Yong Sun Park, Jinhae (KR); Bong Sup Lim, Jinhae (KR)

(73) Assignee: SAMSUNG ELECTRO-MECHANICS CO., LTD.

(21) Appl. No.: 13/022,129

(22) Filed: Feb. 7, 2011

(30) Foreign Application Priority Data
Jun. 16, 2010 (KR) 10-2010-0057048

(51) Int. Cl. H03H 7/01

(52) U.S. Cl. 333/185

(57) ABSTRACT

A multilayer filter includes: a ceramic body in which a plurality of dielectric layers are laminated; an external ground electrode provided on an outer surface of the ceramic body and connected to a ground; an inductor pattern electrode provided on at least one of the dielectric layers and having one end connected to the external ground electrode; a capacitor pattern electrode provided on at least one of the dielectric layers; an external terminal electrode electrically connecting the inductor pattern electrode to the capacitor pattern electrode and forming a closed loop for generating inductance through the external ground electrode; and a variable dielectric layer provided between the capacitor pattern electrode and the inductor pattern electrode and adjusting a magnitude of inductance generated by the inductor pattern electrode.

### CROSS-REFERENCE TO RELATED APPLICATIONS

This application claims the priority of Korean Patent Application No. 10-2010-0057048 filed on Jun. 16, 2010, in the Korean Intellectual Property Office, the disclosure of which is incorporated herein by reference.

### BACKGROUND OF THE INVENTION

1. Field of the Invention

The present invention relates to a multilayer filter, and more particularly, to a multilayer filter which can be miniaturized and can minimize a change of a resonance frequency due to the miniaturization.

2. Description of the Related Art

As the use of mobile communication terminals and wireless communication devices has rapidly increased, a low temperature co-fired ceramic (LTCC) chip filter as well as a surface acoustic wave (SAW) filter has been widely used as a band pass filter (BPF) which is a requisite component of the mobile communication terminals and wireless communication devices, because it is superior in terms of performance, size, reliability, and price.

Also, the size of the chip filter has tended to be smaller as a set product is becoming multifunctional and complex. Due to the tendency to reduce the size of the chip filter, an area of a capacitor electrode constituting capacitance and a length of an inductor electrode constituting inductance become smaller, which causes a resonance frequency to increase.

In order to minimize a change of a resonance frequency due to the miniaturization of the chip filter, a method of increasing a permittivity of a dielectric and a length of an inductor pattern has been used. However, such a method has a limitation and is problematic in that an area of a dielectric layer for an inductor pattern is limited.

As for another method, inductor pattern electrodes are formed on several dielectric layers and are electrically connected together by using vias to thereby minimize a change of a resonance frequency. However, such a method is disadvantageous in that a process is complicated in a structure having vias, and surface roughness of the vias is poor in a process of forming the vias.

Therefore, there is a need for a method which can increase inductance to minimize a change of a resonance frequency due to the miniaturization of a chip filter, without using vias.

### SUMMARY OF THE INVENTION

An aspect of the present invention provides a multilayer filter which can increase inductance to minimize a change of a resonance frequency due to miniaturization.

According to an aspect of the present invention, there is provided a multilayer filter including: a ceramic body in which a plurality of dielectric layers are laminated; an external ground electrode provided on an outer surface of the ceramic body and connected to a ground; an inductor pattern electrode provided on at least one of the dielectric layers and having one end connected to the external ground electrode; a capacitor pattern electrode provided on at least one of the dielectric layers; an external terminal electrode electrically connecting the inductor pattern electrode to the capacitor pattern electrode and forming a closed loop for generating inductance through the external ground electrode; and a variable dielectric layer provided between the capacitor pattern electrode and the inductor pattern electrode and adjusting a magnitude of inductance generated by the inductor pattern electrode.

The external terminal electrode may decrease the magnitude of the inductance generated by the inductor pattern electrode, as an electrode width, parallel to the dielectric layer constituting the ceramic body, increases.

The variable dielectric layer may increase the magnitude of the inductance generated by the inductor pattern electrode, as the amount of laminations contained within the variable dielectric layer increases.

A plurality of inductor pattern electrodes may be provided on the same dielectric layer, and each end of the inductor pattern electrodes may be electrically connected to the external terminal electrode.

The inductor pattern electrodes may be mutually connected on the same dielectric layer.

The inductor pattern electrode may have a curved structure.

A plurality of capacitor pattern electrodes may be provided on the same dielectric layer and spaced apart from one another.

The external ground electrode may be provided on both sides of the ceramic body, and the external terminal electrode may be provided on the outer surface of the ceramic body in which the external ground electrode is not formed.

A single external ground electrode and a single external terminal electrode may be provided on the sides of the ceramic body.

The multilayer filter may further include an internal ground pattern electrode provided on at least one of the dielectric layers constituting the ceramic body, and facing the capacitor pattern electrode to form capacitance.

An end of the internal ground pattern electrode may be electrically connected to the external ground electrode connected to the ground.

The inductor pattern electrode may be disposed above the capacitor pattern electrode within the ceramic body.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view illustrating the outer appearance of a multilayer filter according to an embodiment of the present invention;

FIG. 2 is a schematic exploded perspective view illustrating the inner structure of the multilayer filter according to the embodiment of the present invention;

FIG. 3 is a schematic perspective phantom view illustrating an electrode layer disposed inside the multilayer filter according to the embodiment of the present invention;

FIG. 4 is a schematic view illustrating the implementation of inductance in the multilayer filter according to the embodiment of the present invention;

FIG. 5 is a graph showing the result of an HFSS simulation with respect to a resonance frequency in the multilayer filter according to the embodiment of the present invention; and

FIG. 6 is a graph showing the result of an HFSS simulation with respect to a resonance frequency according to the amount of laminations (lamination height) of a variable dielectric layer provided in the multilayer filter according to the embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions may be exaggerated for clarity. Like reference numerals in the drawings denote like elements, and thus descriptions thereof will be omitted.

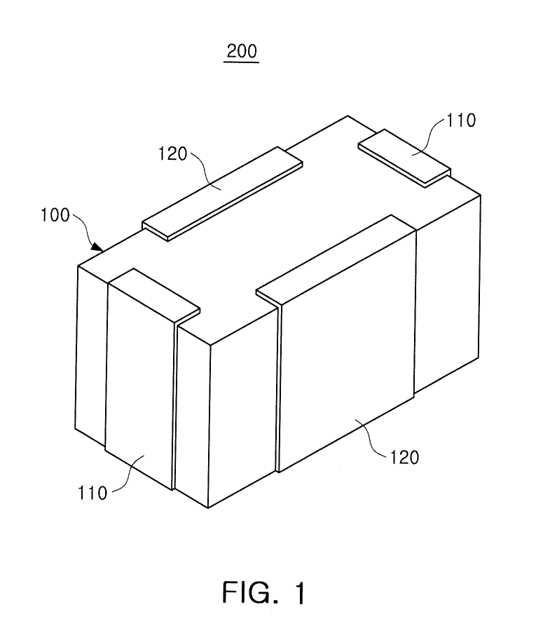

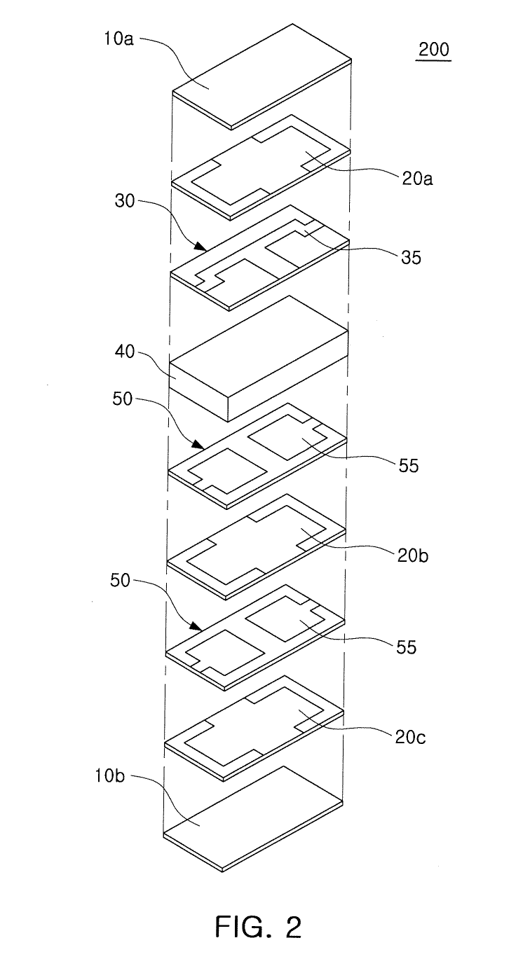

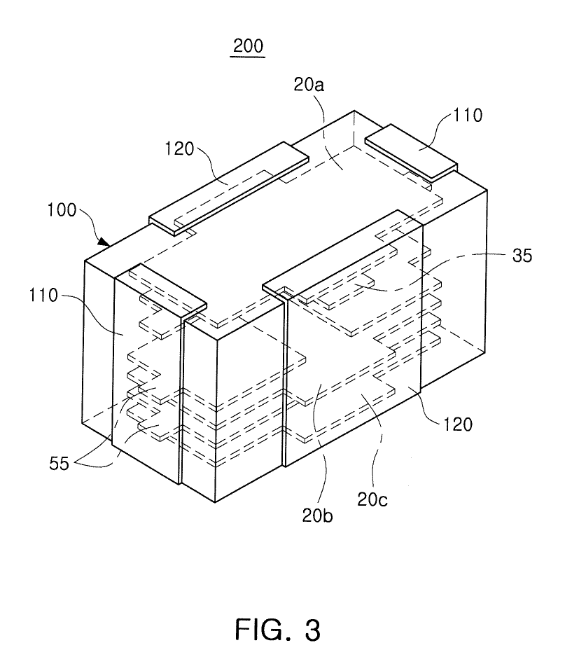

FIG. 1 is a schematic perspective view illustrating the outer appearance of a multilayer filter according to an embodiment of the present invention. FIG. 2 is a schematic exploded perspective view illustrating the inner structure of the multilayer filter according to the embodiment of the present invention. FIG. 3 is a schematic perspective phantom view illustrating an electrode layer disposed inside the multilayer filter according to the embodiment of the present invention.

Referring to FIG. 1, the multilayer filter 200 according to the embodiment of the present invention may include a ceramic body 100, external terminal electrodes 110, and external ground electrodes 120.

The ceramic body 100 has a structure in which a plurality of dielectric layers are laminated. The ceramic body 100 may have a rectangular parallelepiped shape or a shape similar thereto. The external terminal electrodes 110, which will be described later, may be formed on an outer surface of the ceramic body 100.

The external terminal electrodes 110 are a pair of electrodes provided on two sides of the ceramic body 100 and serve as input and output electrodes of the multilayer filter 200. The external ground electrodes 120 are a pair of electrodes provided on another two sides of the ceramic body 100, on which the external terminal electrodes 110 are not formed.

That is, the external ground electrodes 120 are formed on two sides of the ceramic body 100, and the external terminal electrodes 110 are formed on the outer surface of the ceramic body 100, on which the external ground electrodes 120 are not formed.

Also, a single external ground electrode 120 and a single external terminal electrode 110 may be formed on the sides of the ceramic body 100.

The bottom surface of the ceramic body 100 is a surface facing an external substrate (not shown) on which the multilayer filter 200 is mounted.

The inner structure of the multilayer filter 200 will be described below.

Referring to FIGS. 2 and 3, the multilayer filter 200 according to the embodiment of the present invention may include the ceramic body 100, a capacitor pattern electrode 55, an inductor pattern electrode 35, the external terminal electrodes 110, and a variable dielectric layer 40.

Dielectric cover layers 10a and 10b may be formed on uppermost and lowermost layers of the ceramic body 100. The dielectric cover layers 10a and 10b may serve as a cover which protects the inner structure of the multilayer filter 200.

Materials for the dielectric cover layers 10a and 10b are not specifically limited. For example, the dielectric cover layers 10a and 10b may be made of various ceramic materials.

The capacitor pattern electrode 55 may be formed on a first dielectric layer 50 which is one of a plurality of dielectric layers constituting the ceramic body 100. The first dielectric layer 50 may be any one of the dielectric layers constituting the ceramic body 100. The capacitor pattern electrode 55 may be formed on the plurality of dielectric layers.

A plurality of capacitor pattern electrodes 55 may be formed on the first dielectric layer 50. The shapes of the capacitor pattern electrodes 55 are not specifically limited.

In addition, the capacitor pattern electrodes 55 may be spaced apart from one another on the same dielectric layer. The capacitor pattern electrodes 55 may form capacitance between internal ground pattern electrodes 20a, 20b and 20c, which will be described later.

By forming the capacitor pattern electrodes 55 spaced apart from one another on the same dielectric layer, a plurality of capacitances may be formed between the internal ground pattern electrodes 20a, 20b and 20c.

The capacitor pattern electrode 55 may has one end electrically connected to the external terminal electrode 110 and the other end opened on a surface of the first dielectric layer 50.

The capacitor pattern electrode 55 may be formed in parallel to the internal ground pattern electrodes 20a, 20b and 20c. When an external voltage is applied, charges are accumulated on the capacitor pattern electrode 55 to form capacitance.

Both ends of the internal ground pattern electrodes 20a, 20b and 20c extend toward the external ground electrodes 120 in order for electrical connection to the external ground electrodes 120 which are connected to the ground.

The capacitance generated in the above manner may be determined by the area of the capacitor pattern electrodes 55 facing each other, the interval of the internal ground pattern electrodes 20a, 20b and 20c, and the permittivity of the ceramic constituting the ceramic body 100.

The inductor pattern electrode 35 may be formed on a second dielectric layer 30 which is one of the plurality of dielectric layers constituting the ceramic body 100. The second dielectric layer 30 may be any one of the dielectric layers constituting the ceramic body 100.

Also, the inductor pattern electrode 35 may extend by a predetermined length so that both ends thereof are connected to the external terminal electrodes 110.

In the implementation of the inductance, the inductor pattern electrode 35 is connected to the external terminal electrodes 110 serving as the input and output electrodes, whereby it is electrically connected to the input and output electrodes.

Also, a plurality of inductor pattern electrodes 35 may be formed on the same dielectric layer and mutually connected.

Therefore, by mutually connecting the inductors formed in the input and output sides, the multilayer filter 200 according to the embodiment of the present invention may serve as a band pass filter as a whole.

The inductor pattern electrode 35 may have a straight or curved structure having a predetermined length. For example, the inductor pattern electrode 35 may have a meander shape or a spiral shape.

Compared with the inductor pattern electrode 35 having a straight shape, the inductor pattern electrode 35 having a curved or meander shape may implement a desired inductance in a smaller area. Consequently, the size of the multilayer filter 200 may be further reduced.

The external terminal electrode 110 is a terminal electrode formed on the outer surface of the ceramic body 100 and may electrically connect the capacitor pattern electrode 55 to the inductor pattern electrode 35.

The external terminal electrode 110 refers to the input terminal electrode and the output terminal electrode. An electric signal having a predetermined frequency and voltage is input through the external terminal electrode 110 formed on one side of the ceramic body 100 and is output through the external terminal electrode 110 formed on the other side thereof.

At this time, the capacitor pattern electrode 55 and the inductor pattern electrode 35 may implement an LC resonance circuit.

The external terminal electrode 110 connects the inductor pattern electrode 35 to the capacitor pattern electrode 55, and a closed loop 130 is formed by the external terminal electrode 110 and the external ground electrode 120 connected to the ground, whereby the inductor pattern electrode 35 generates inductance.

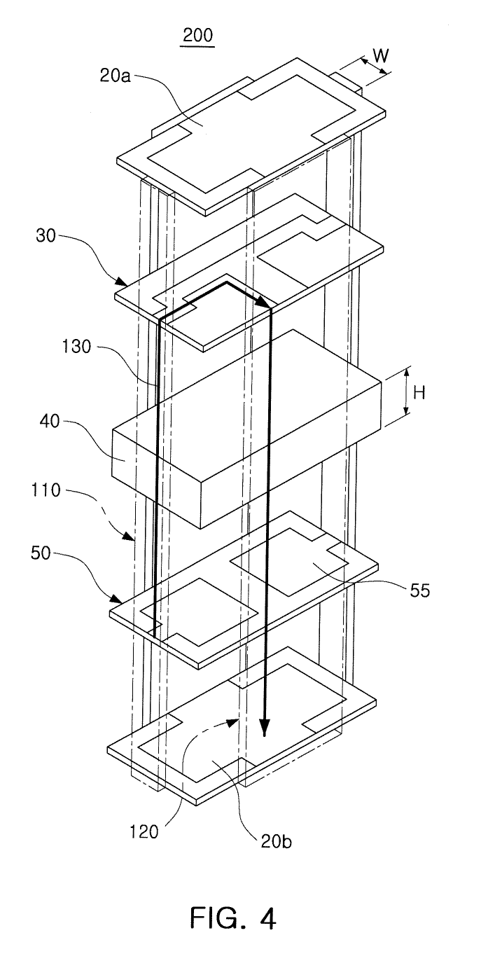

The generation of the inductance by the external terminal electrode 110 will be described later with reference to FIG. 4.

The variable dielectric layer 40 is provided between the first dielectric layer 50 and the second dielectric layer 30 and may adjust the magnitude of the inductance generated by the inductor pattern electrode 35.

That is, the variable dielectric layer 40 is provided between the capacitor pattern electrode 55 and the inductor pattern electrode 35 and expands the space of the closed loop 130 formed by the external terminal electrode 110, thereby increasing an inductance component generated by the inductor pattern electrode 35.

In addition, as the lamination number of the variable dielectric layer 40 increases, the lamination height of the variable dielectric layer 40 increases and the inductance component generated by the inductor pattern electrode 35 increases.

FIG. 4 is a schematic view illustrating the implementation of the inductance in the multilayer filter according to the embodiment of the present invention.

Referring to FIG. 4, the inductance by the inductor pattern electrode 35 may be formed by the inductor pattern electrode 35, the external terminal electrode 110, and the external ground electrode 120.

The inductor pattern electrodes 35 formed on the second dielectric layer 30 are mutually connected in the center of the second dielectric layer 30, and their ends extend toward the external terminal electrodes 110 and are electrically connected thereto.

Therefore, the inductor pattern electrodes 35 are connected to the capacitor pattern electrodes 55 through the external terminal electrodes 110. In this manner, the same voltage may be applied from the input side to the inductors formed by the inductor pattern electrodes 35 and the capacitors formed by the capacitor pattern electrodes 55.

In addition, the other ends of the inductor pattern electrodes 35 formed on the second dielectric layer 30 are connected to the external ground electrode 120 connected to the ground, thereby implementing the inductors. The external ground electrodes 120 are connected to the internal ground pattern electrodes 20a, 20b and 20c, and the capacitor pattern electrodes 55 forming the coupling with the internal ground pattern electrodes 20a, 20b and 20c can implement the capacitors.

Therefore, the inductance by the inductor pattern electrode 35 can be implemented by forming the closed loop 130 by means of the external terminal electrode 110. Consequently, the LC resonance circuit can be configured.

The multilayer filter 200 according to the embodiment of the present invention can solve the problem caused during the formation of the vias because it is not necessary to form the vias on the second dielectric layer 30, on which the inductor pattern electrodes 35 are formed, in order to form the closed loop 130 for the implementation of the inductance.

Additionally, compared with the method of forming the vias, the use of the external terminal electrode 110 can expand the path of the closed loop 130 for the formation of the inductance. Thus, a linked magnetic flux area expands to thereby increase the magnitude of the inductance.

Furthermore, the external terminal electrode 110 may reduce the magnitude of the inductance generated by the inductor pattern electrode 35 according to the increase of an electrode width W parallel to the dielectric layer constituting the ceramic body 100.

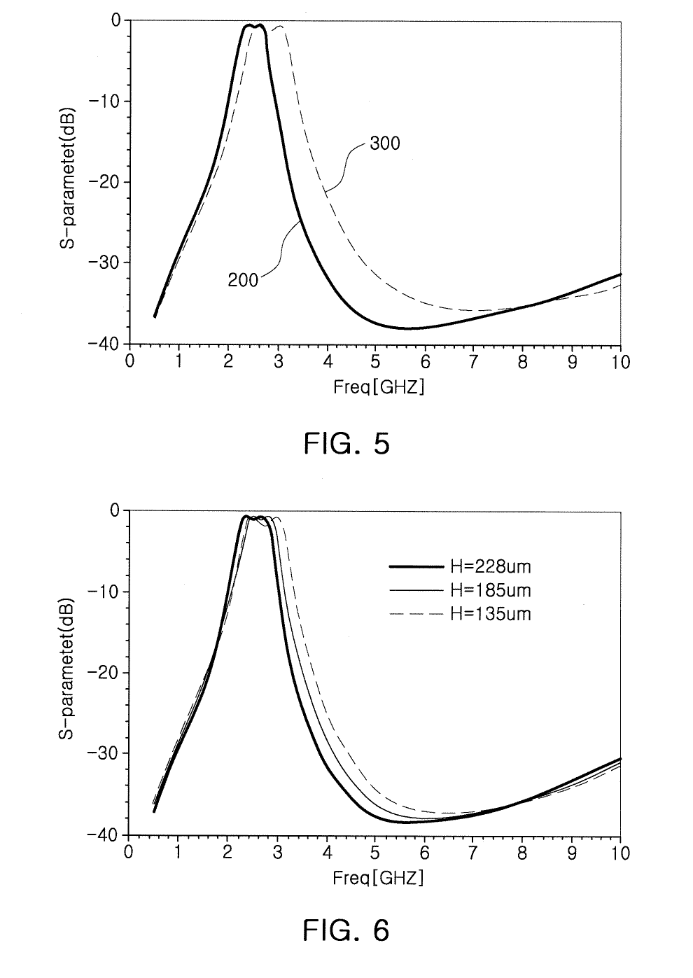

FIG. 5 is a graph showing the result of an HFSS simulation with respect to the resonance frequency in the multilayer filter according to the embodiment of the present invention. FIG. 6 is a graph showing the result of an HFSS simulation with respect to the resonance frequency according to the lamination number (lamination height) of the variable dielectric layer provided in the multilayer filter according to the embodiment of the present invention.

Referring to FIG. 5, the resonance frequency of the multilayer filter 200 using the external terminal electrode 110 for forming the closed loop 130 for the implementation of the inductance is lower than that of the multilayer filter 300 implemented by forming the vias in the dielectric layers on which the inductor pattern electrodes are formed.

Since the resonance frequency of the LC resonance circuit is

$$\frac{1}{2 π \sqrt{LC}} ,$$

it can be seen that the magnitude of the inductance was increased from the fact that the resonance frequency was reduced when the area of the capacitor pattern electrode was constant.

That is, the inductance value can be increased while achieving the miniaturization of the multilayer filter, thereby minimizing the change of the resonance frequency.

Referring to FIG. 6, it can be seen that the resonance frequency was reduced with the increase in the amount of laminations contained within the variable dielectric layers 40 inserted between the inductor pattern electrode 35 and the capacitor pattern electrode 55, that is, a change in the lamination height (H in FIG. 4) of the variable dielectric layers 40.

Like the result of FIG. 5, the result of FIG. 6 shows the increase in the inductance value. Since the desired inductance value is obtained by adjusting the lamination height of the variable dielectric layers 40, the miniaturization of the multilayer filter can be achieved and the change of the resonance frequency can be minimized.

According to the embodiments of the invention, the multilayer filter 200 in which the closed loop is formed by using the external terminal electrode 110 for the implementation of the inductance can increase the inductance while achieving the miniaturization, thereby minimizing the change of the resonance frequency.

Furthermore, the desired inductance value can be obtained by adjusting the electrode width W of the external terminal electrode 110 or the lamination height H of the variable dielectric layer 40.

As set forth above, according to exemplary embodiments of the present invention, the inductance by the inductor pattern electrode may be implemented using the external terminal electrode.

Furthermore, since the inductance is implemented using the external terminal electrode, the linked magnetic flux area may be expanded.

Moreover, the magnitude of the inductance may be increased by adjusting the variable dielectric layer disposed between the capacitor pattern electrode and the inductor pattern electrode.

While the present invention has been shown and described in connection with the exemplary embodiments, it will be apparent to those skilled in the art that modifications and variations can be made without departing from the spirit and scope of the invention as defined by the appended claims.

What is claimed is:

1. A multilayer filter comprising:
a ceramic body in which a plurality of dielectric layers are laminated;
an external ground electrode provided on an outer surface of the ceramic body and connected to a ground;
an inductor pattern electrode provided on at least one of the dielectric layers and having one end connected to the external ground electrode;
a capacitor pattern electrode provided on at least one of the dielectric layers;
an external terminal electrode electrically connecting the inductor pattern electrode to the capacitor pattern electrode and forming a closed loop for generating inductance through the external ground electrode; and
a variable dielectric layer provided between the capacitor pattern electrode and the inductor pattern electrode and adjusting a magnitude of inductance generated by the inductor pattern electrode.

2. The multilayer filter of claim 1, wherein the external terminal electrode reduces the magnitude of the inductance generated by the inductor pattern electrode, as an electrode width, parallel to the dielectric layer constituting the ceramic body, increases.

3. The multilayer filter of claim 1, wherein the variable dielectric layer increases the magnitude of the inductance generated by the inductor pattern electrode, as the number of laminations contained within the variable dielectric layer increases.

4. The multilayer filter of claim 1, wherein a plurality of inductor pattern electrodes are provided on the same dielectric layer, and each end of the inductor pattern electrodes is electrically connected to the external terminal electrode.

5. The multilayer filter of claim 4, wherein the inductor pattern electrodes are mutually connected on the same dielectric layer.

6. The multilayer filter of claim 1, wherein the inductor pattern electrode has a curved structure.

7. The multilayer filter of claim 1, wherein a plurality of capacitor pattern electrodes are provided on the same dielectric layer and spaced apart from one another.

8. The multilayer filter of claim 1, wherein the external ground electrode is provided on both sides of the ceramic body, and the external terminal electrode is provided on the outer surface of the ceramic body in which the external ground electrode is not formed.

9. The multilayer filter of claim 8, wherein a single external ground electrode and a single external terminal electrode are provided on the sides of the ceramic body.

10. The multilayer filter of claim 1, further comprising an internal ground pattern electrode provided on at least one of the dielectric layers constituting the ceramic body, and facing the capacitor pattern electrode to form capacitance.

11. The multilayer filter of claim 10, wherein an end of the internal ground pattern electrode is electrically connected to the external ground electrode connected to the ground.

12. The multilayer filter of claim 1, wherein the inductor pattern electrode is disposed above the capacitor pattern electrode within the ceramic body.
